(19) United States
(12) Patent Application Publication
(10) Pub. No.: US 2007/0279263 A1
(43) Pub. Date: Dec. 6, 2007

(54) NETWORK DEVICE AND METHOD FOR RECOVERING CLOCK SIGNAL THEREOF

(75) Inventors: Tsung-hsi Lee, Tu-Cheng (TW); Chen-wen Huang, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng,Taipei Hsien (US)

(21) Appl. No.: 11/752,313

(22) Filed: May 23, 2007

(30) Foreign Application Priority Data
Jun. 2, 2006 (TW) 95119625

(51) Int. Cl. H03M 7/34

(52) U.S. Cl. 341/51

(57) ABSTRACT

A network device communicating with a digital clock supply (DCS), a first network, and a second network, includes an input port, a parsing module, and a synthesis module. The input port receives a digital clock signal from the DCS. The parsing module parses the digital clock signal into a plurality of digital clock signals with different frequencies. The synthesis module uses the digital clock signals to synthesize a new digital clock signal. Phase of the new digital clock signal is the same as that of the digital clock signal from the DCS.

### BACKGROUND OF THE INVENTION

1. Field of the Invention

The invention relates to a network device and method for recovering a clock signal, and particularly to a central office device and method for recovering a clock signal.

2. Description of related art

Nowadays, service providers provide network service to subscribers via a plurality of central office devices. To ensure proper operation of the central office devices, digital clock supplies (DCSs) are employed to provide synchronous clock signals thereto.

However, a common problem with existing central office devices is that, as the number of DCSs increases, it is difficult to implement synchronization of the digital clock signals.

### SUMMARY OF THE INVENTION

An exemplary embodiment of the present invention provides a network device communicating with a digital clock supply (DCS), a first network, and a second network respectively. The network device includes an input port, a parsing module, and a synthesis module. The input receives a digital clock signal from the DCS. The parsing module parses the digital clock signal into a plurality of digital clock signals with different frequencies. The synthesis module synthesizes the digital clock signals to generate a new digital clock signal. Phase of the new digital clock signal is the same as the digital clock signal from the DCS.

Another exemplary embodiment of the present invention provides a method for recovering a digital clock signal in a network device. The network device is communicated to a digital clock supply (DCS). The method includes: receiving a digital clock signal from the DCS; parsing the digital clock signal into a plurality of digital clock signals with different frequencies; and synthesizing the digital clock signals to generate a new digital clock signal. Phase of the new digital clock signal is the same as that of the digital clock signal from the DCS.

Other advantages and novel features will become more apparent from the following detailed description of preferred embodiments when taken in conjunction with the accompanying drawings, in which:

### BRIEF DESCRIPTION OF THE DRAWINGS

FIG. 1 is a schematic diagram illustrating an application environment of a network device of an exemplary embodiment of the present invention;

FIG. 2 is a block diagram of the network device in FIG.1; and

FIG. 3 is a flowchart of a method for recovering a digital clock signal of another exemplary embodiment of the present invention.

### DETAILED DESCRIPTION OF THE INVENTION

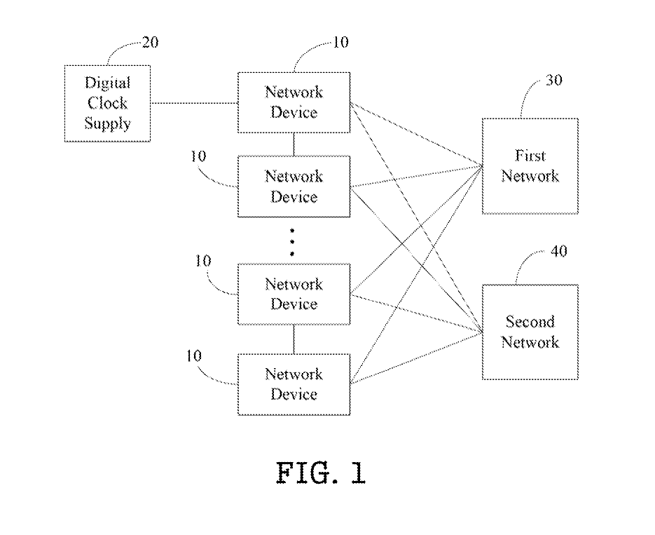

FIG. 1 is a schematic diagram illustrating an application environment of a network device of an exemplary embodiment of the present invention. A plurality of network devices 10 and a digital clock supply (DCS) 20 are arranged in a central office of a service provider (not shown). The network devices 10 are communicated to a first network 30 and a second network 40. The DCS 20 provides a digital clock signal to one of the network devices 10. The one of the network devices 10 operates according to the digital clock signal, and generates a new digital clock signal for a next network device 10. In the exemplary embodiment, the new digital clock signal is the same phase as the digital clock signal from the DCS 20.

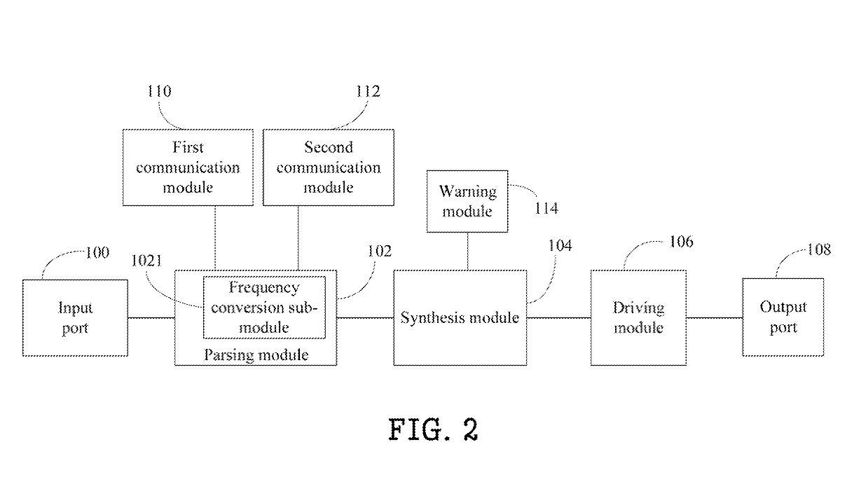

FIG. 2 is a block diagram of the network device 10 in FIG.1. The network device 10 includes an input port 100, a parsing module 102, a synthesis module 104, a driving module 106, an output port 108, a first communication module 110, a second communication module 112, and a warning module 114.

The input port 100 receives the digital clock signal from the DCS 20. In the exemplary embodiment, the digital clock signal is an alternate mark inversion (AMI) signal.

The parsing module 108 parses the digital clock signal into a plurality of digital clock signals with different frequencies. In the exemplary embodiment, the parsing module 108 parses the digital clock signal into a first digital clock signal, a second digital clock signal, and a third digital clock signal. Frequencies of the first digital clock signal, the second digital clock signal, and the third digital clock signal are respectively 64 KHz, 8 KHz, and 400 Hz. The parsing module 108 includes a frequency conversion sub-module 1021. The frequency conversion sub-module 1021 is used for converting the frequency of the first clock signal to generate a new first clock signal. In the exemplary embodiment, the frequency conversion sub-module 1021 converts the frequency of the first clock signal from 64 KHz to 8.192 MHz, therefore the frequency of the new first clock signal is 8.192 MHz.

The synthesis module 104 uses the digital clock signals to synthesize a new digital clock signal. In the exemplary embodiment, phase of the new digital clock signal is the same as that of the digital clock signal from the DCS 20.

The driving module 106 processes intensity of the new digital clock signal and generates a high intensity digital clock signal. In the exemplary embodiment, the driving module 106 is a booster transformer for boosting voltage of the new digital clock signal.

The output port 108 transmits the high intensity digital clock signal to another network device 10.

The first communication module 110 provides the first digital clock signal, the second digital clock signal, and the third digital clock signal to the first network 30. In the exemplary embodiment, the first network 30 is an integrated services digital network (ISDN).

The second communication module 110 provides the first digital clock signal, and the second clock signal to the second network 40. In the exemplary embodiment, the second network 40 is a voice over Internet protocol (VoIP) network.

The warning module 11 4 generates a warning signal when the digital clock signals are no longer received. In the exemplary embodiment, the warning module 114 turns on a light emitting diode to generate the warning signal.

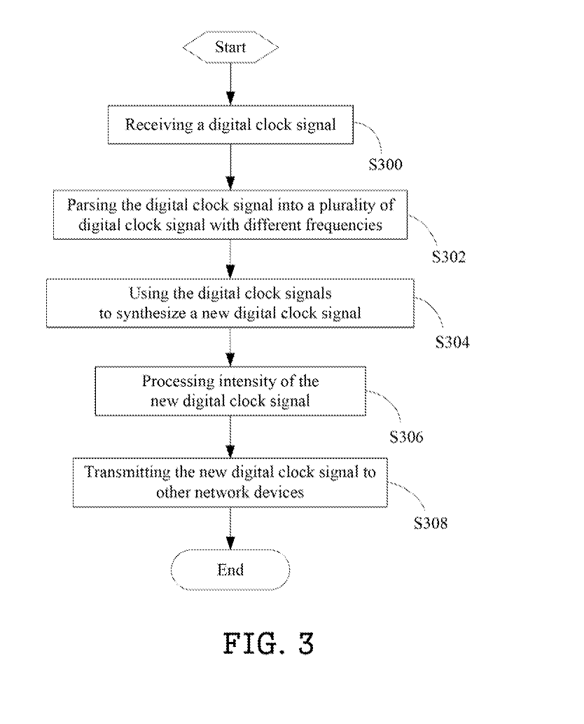

FIG. 3 is a flowchart of a method for recovering and synchronizing a digital clock signal of another exemplary embodiment of the present invention in a network device.

In step S300, the input port 100 receives the digital clock signal from the DCS 20. In the exemplary embodiment, the digital clock signal is an alternate mark inversion (AMI) signal.

In step S302, parsing module 102 parses the digital clock signal into a plurality of digital clock signals with different frequencies. In the exemplary embodiment, the parsing module 102 parses the digital clock signal into a first digital clock signal, a second digital clock signal, and a third digital clock signal. Frequencies of the first digital clock signal, the second digital clock signal, and the third digital clock signal are respectively 64 KHz, 8 KHz, and 400 Hz.

In step S304, the synthesis module 104 uses the digital clock signals to synthesize a new digital clock signal. In the exemplary embodiment, phase of the new digital clock signal is the same as the digital clock signal from the DCS 20.

In step S306, The driving module 106 processes intensity of the new digital clock signal and generates a high intensity digital clock signal. In the exemplary embodiment, the voltage of the high intensity digital clock signal is 3.3V.

In step S308, the output port 108 transmits the high intensity digital clock signal to other network devices 10.

While embodiments and methods of the present invention have been described above, it should be understood that they have been presented by way of example only and not by way of limitation. Thus the breadth and scope of the present invention should not be limited by the above-described exemplary embodiments, but should be defined only of the following claims and their equivalents.

What is claimed is:

1. A network device communicating with a digital clock supply (DCS), a first network, and a second network, the network device comprising:
an input port for receiving a digital clock signal from the DCS;
a parsing module for parsing the digital clock signal into a plurality of digital clock signals with different frequencies; and
a synthesis module for using the digital clock signals to synthesize a new digital clock signal;
wherein phase of the new digital clock signal is the same as that of the digital clock signal from the DCS.

2. The network device as claimed in claim 1, further comprising a driving module for processing intensity of the new digital clock signal.

3. The network device as claimed in claim 2, wherein the driving module is a booster transformer for boosting voltage of the new digital clock signal.

4. The network device as claimed in claim 2, further comprising an output for transmitting a boosted new digital clock signal to other network devices.

5. The network device as claimed in claim 1, further comprising a warning module for generating a warning signal when the plurality of digital clock signals disappears.

6. The network device as claimed in claim 5, wherein the warning module turns on a light emitting diode to generate the warning signal.

7. The network device as claimed in claim 1, wherein the first network is an integrated services digital network.

8. The network device as claimed in claim 7, wherein the second network is a voice over Internet protocol network.

9. The network device as claimed in claim 7, wherein the plurality of digital clock signals with different frequencies comprise a first digital clock signal, a second digital clock signal, and a third digital clock signal, frequencies of which are respectively 64 KHz, 8 KHz, and 400 Hz.

10. The network device as claimed in claim 1, wherein the digital clock signal is an alternate mark inversion (AMI) signal.

11. A method for recovering and synchronizing a digital clock signal in a network device, the network device communicated to a digital clock supply (DCS), the method comprising:
receiving a digital clock signal from the DCS;
parsing the digital clock signal into a plurality of signals with different frequencies; and
using the plurality of signals to synthesize a new digital clock signal, wherein phase of the new digital clock signal is the same as that of the digital clock signal from the DCS.

12. The method as claimed in claim 11, further comprising processing intensity of the new digital clock signal.

13. The method as claimed in claim 12, further comprising boosting voltage of the new digital clock signal.

14. The method as claimed in claim 13, further comprising transmitting the new digital clock signal to other network device.

15. A method for recovering and synchronizing a digital clock signal in a network device, comprising steps of:
receiving a digital clock signal in a network device from a digital clock supply (DCS) data-communicable with said network device;
parsing said digital clock signal into a plurality of clock signals with different frequencies for use of said network device;
synthesizing a new digital clock signal in said network device so that phase of said new digital clock signal is same as phase of said received digital clock signal from said DCS; and
outputting said new digital clock signal to another network device data-communicable with said network device for use of said another network device.

16. The method as claimed in claim 15, wherein said new digital clock signal is synthesized by using said plurality of clock signals parsed in said network device.
